(19) United States
(12) Patent Application Publication
(10) Pub. No.: US 2008/0087991 A1
(43) Pub. Date: Apr. 17, 2008

(54) Vertical light source package

(76) Inventors: Chiang Sun Cheah, Butterworth (MY); Ban Kuan Koay, Bayan Lepas (MY)

Correspondence Address: Kathy Manke;Avago Technologies Limited, 4380 Ziegler Road, Fort Collins, CO, 80525, US

(21) Appl. No.: 11/580,391

(22) Filed: Oct. 13, 2006

(51) Int. Cl. H01L 23/495

(52) U.S. Cl. 257/666

(57) ABSTRACT

A vertical light source package uses leadframes with leads that extend in the same predefined direction. The leadframes are at least partially positioned in a structural body of the vertical light source package. The vertical light source package includes a light emitting device, such as a vertical-cavity surface-emitting laser, that is situated on one of the leadframes and electrically connected to the other leadframe.

### BACKGROUND OF THE INVENTION

Laser diodes, such as vertical-cavity surface-emitting lasers (VCSELs), are widely used as light sources for various applications, such as optical indicators, optical communication systems and optical navigation systems. A particular application of interest is the use of a VCSEL as the light source for an optical navigation system in a product, such as an optical computer mouse. In an optical computer mouse, the VCSEL is used to project a laser light onto a target surface, which is reflected by the target surface. The reflected light is then received at an image sensor array to capture frames of image data. The frames of image data are then processed to estimate the movements or the motion of the computer mouse to control the movements of a cursor on a computer screen.

VCSELs are usually manufactured in VCSEL packages. A conventional VCSEL package typically includes a VCSEL die, two leadframes and a structural body. The VCSEL chip is mounted on one of the leadframes and is bondwired to the other leadframe. The leadframes are bent so that the leadframes extend in a direction, which is opposite of the direction of light emitted from the VCSEL die. The structural body is cylindrical in shape and is formed around the VCSEL die so that the light from the VCSEL die is emitted out of one end of the structural body and the leadframes protrude from the other end of the structural body. The protruding leadframes from the structural body are used to physically and electrically connect the VCSEL package onto a printed circuit board (PCB).

A concern with the conventional VCSEL package described above is that the leadframes need to be quite long to be attached to a PCB. This requirement causes high wastage of leadframe material since a significant amount of leadframe material is scrapped after the leadframes are trimmed. Furthermore, the number of leadframes for VCSEL packages that can be made per unit area of leadframe material is limited due to the long leadframes that must be trimmed from the leadframe material.

In view of these concerns, there is a need for a vertical light source package, such as a VCSEL package, that does not require long leadframes, which would decrease wastage of leadframe material and increase the number of leadframes that can be made per unit area of leadframe material.

### SUMMARY OF THE INVENTION

A vertical light source package uses leadframes with leads that extend in the same predefined direction. The leadframes are at least partially positioned in a structural body of the vertical light source package. The vertical light source package includes a light emitting device, such as a vertical-cavity surface-emitting laser, that is situated on one of the leadframes and electrically connected to the other leadframe. The configuration of the leadframes allows less leadframe material to be wasted during manufacture. In addition, the configuration of the leadframes allows more leadframes for vertical light source packages to be produced per unit area of leadframe material.

A vertical light source package in accordance with an embodiment of the invention comprises a structural body, a light emitting device, a first leadframe and a second leadframe. The structural body includes a light output end. The light emitting device is positioned in the structural body such that light from the light emitting device is emitted from the light output end of the structural body. The light emitting device may be a vertical-cavity surface-emitting laser. The first leadframe is at least partially positioned in the structural body. The first leadframe includes a first region and a first elongate lead that extends from the first region in a predefined direction. The light emitting device is situated on the first region of the first leadframe. The second leadframe is at least partially positioned in the structural body. The second leadframe includes a second region and a second elongate lead that extends from the second region in the predefined direction. The light emitting device is electrically connected to the second region of the second leadframe.

Other aspects and advantages of the present invention will become apparent from the following detailed description, taken in conjunction with the accompanying drawings, illustrated by way of example of the principles of the invention.

### BRIEF DESCRIPTION OF THE DRAWINGS

FIG. 1 is a perspective view of a vertical light source package in accordance with an embodiment of the invention.

FIG. 2 is a top view of the vertical light source package.

FIG. 3 is a diagram of an external lead of the vertical light source package in accordance with an alternative embodiment of the invention.

FIG. 4 is a perspective view of a vertical light source package and a female connector in accordance with another embodiment of the invention.

### DETAILED DESCRIPTION

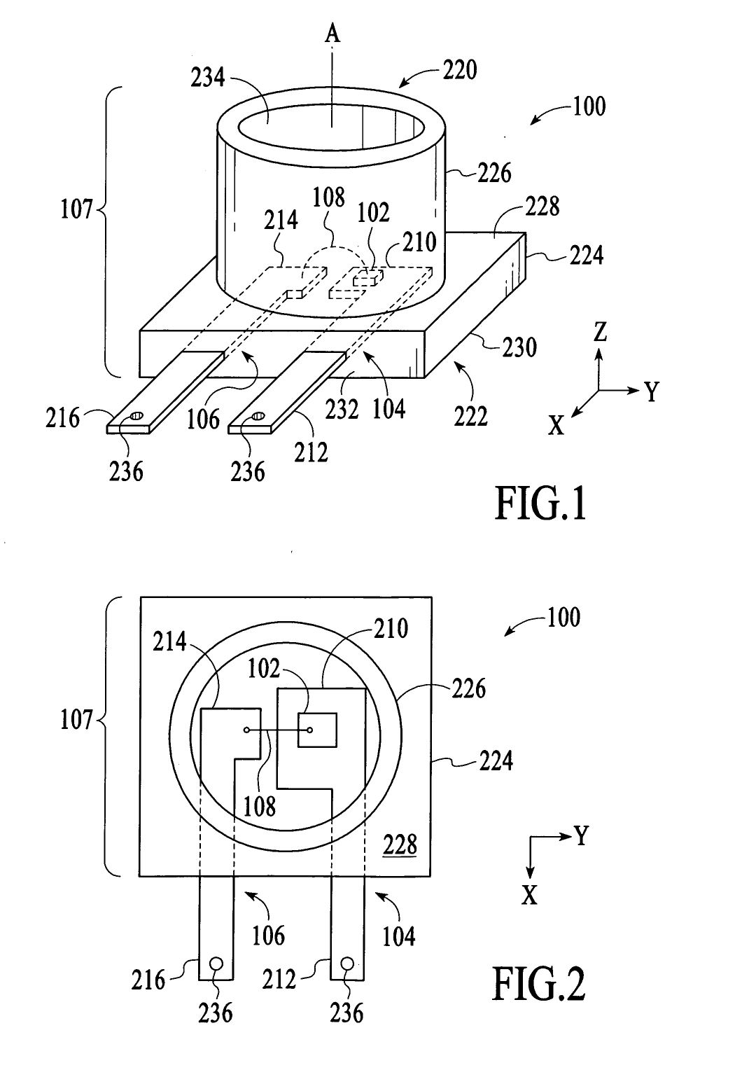

With reference to FIGS. 1 and 2, a vertical light source package 100 in accordance with an embodiment of the invention is shown. FIG. 1 is a perspective view of the vertical light source package 100. FIG. 2 is a top view of the vertical light source package 2. The vertical light source package 100 can be used as a light source-for various applications, such as optical indicators, optical communication systems and optical navigation systems. As described in detail below, the vertical light source package 100 includes shorter leadframes than conventional VCSEL packages. Consequently, less leadframe material is wasted to produce the leadframes of the vertical light source package 100. In addition, more leadframes for vertical light source packages similar to the vertical light source package 100 can be produced per unit area of leadframe material due to the shorter leadframes. Other advantages of the vertical light source package 100 are also described below.

As shown in FIGS. 1 and 2, the light source package 100 includes a light emitting device 102, leadframes 104 and 106 and a structural body 107. In this embodiment, the light emitting device 102 is a semiconductor die that is configured to emit light when activated. In particular, the light emitting device 102 is a vertical-cavity surface-emitting Laser (VCSEL) die. Thus, the light emitting device 102 emits light from the top surface of the light emitting device. However, in other embodiments, the light emitting device 102 can be any type of a device that emits light, such as any light emitting diode and any laser diode. The light emitting device 102 is mounted on the leadframe 104 using an adhesive material, which is also electrically conductive. Thus, the light emitting device 102 is both physically and electrically connected to the leadframe 104. The light emitting device 102 is also electrically connected to the other leadframe 106 via a bondwire 108.

The leadframes 104 and 106 of the vertical light source package 100 are thin strips of electrically conductive material, such as copper. The leadframes 104 and 106 are formed by trimming a thin sheet of leadframe material. In this embodiment, the leadframes 104 and 106 are configured to be flat so that the entire lengths of the leadframes are parallel to a plane. Thus, the leadframes 104 and 106 have not been bent after the leadframes have been trimmed from a sheet of leadframe material. The leadframe 104 includes a region 210 on which the light emitting device 102 is situated. The leadframe 104 also includes an elongate lead 212 that extends from the region 210 in the X direction. Similarly, the leadframe 106 includes a region 214 to which the bondwire 108 is connected. The leadframe 106 also includes an elongate lead 216 that extends from the region 214 in the same X direction. Thus, the leads 212 and 216 of the leadframes 104 and 106, respectively, are parallel to each other and both of the leads 212 and 216 extend in the same direction. As best shown in FIG. 1, the regions 210 and 214 of the leadframes 104 and 106, respectively, are positioned in the structural body 107. Thus, the light emitting device 102 and the bondwire 108 are also positioned in the structural body 107. The leads 212 and 216 of the leadframes 104 and 106, respectively, are partially positioned in the structural body 107. Thus, portions of the leads 212 and 216 protrude from the structural body 107. Since the leads 212 and 216 of the leadframes 104 and 106, respectively, extend in the same direction, the leads 212 and 216 protrude from the structural body 107 in the same direction.

The lengths of the leads 212 and 216 of the leadframes 104 and 106, respectively, are shorter than the leads of conventional VCSEL packages. Consequently, the leadframes 104 and 106 of the vertical light source package 100 can be produced from a smaller area of a sheet of leadframe material than the leadframes of conventional VCSEL packages. Thus, less leadframe material is wasted to produce the leadframes 104 and 106 of the vertical light source package 100 when compared to the conventional leadframes. In addition, more leadframes 104 and 106 can be produced per unit area of leadframe material when compared to the conventional leadframes.

The structural body 107 of the vertical light source package 100 provides the structural support to secure the leadframes 104 and 106 in place. As best shown in FIG. 1, the structural body 107 has a front end 220 and a back end 222, which are opposite ends of the structural body. As described below, the front end 220 is used to output light from the light emitting device 102 and the back end 222 can be used to optically align the vertical light source package 100.

The structural body 107 includes a base portion 224 and a cylindrical portion 226. In this embodiment, the base portion 224 is shaped as a rectangular solid. However, in other embodiments, the base portion 224 can be shaped in other configurations. In this embodiment, the base portion 224 includes an upper surface 228, a lower surface 230 and four side surfaces 232. The upper surface 228 of the base portion 224 faces the cylindrical portion 226 of the structural body 107. The lower surface 230 of the base portion 224, which is on the opposite side of the base portion as the upper surface 228, corresponds to the back end 222 of the structural body 107. The lower surface 230 is a planar surface. As best shown in FIG. 1, the leads 212 and 216 of the leadframes 104 and 106, respectively, protrude from the structural body 107 at one of the side surfaces 232 of the structure body.

The cylindrical portion 226 of the structural body 107 is connected to the base portion 224 such that the axis A of the cylindrical portion is perpendicular to the upper surface 228 of the base portion. In the illustrated embodiment, the cylindrical portion 226 of the structural body 107 is configured as a cylindrical shell. Thus, the cylindrical portion 226 includes a cylindrical hole 234, which extends down to the base portion 224, exposing portions of the leadframes 104 and 106, including the light emitting device 102 mounted on the leadframe 104. The light emitting device 102 is positioned in the structural body 107 such that the light emitting surface of the light emitting device, i.e., the upper surface of the light emitting device, is perpendicular to the axis A of the cylindrical portion 226. Thus, the light emitted from the light emitting device 102 will propagate in a direction along the axis A of the cylindrical portion 226 and will be emitted out of the cylindrical hole 234 of the cylindrical portion 224 at the exposed end of the cylindrical portion, which corresponds to the front end 220 of the vertical light source package 100. Thus, the exposed end of the cylindrical portion 226 is the light output end of the structural body 107. Furthermore, the light emitting device 102 is positioned in the structural body 107 such that the light emitting surface of the light emitting device is substantially parallel to the lower surface 230 of the base portion 224. Thus, the light emitting direction of the light emitting device 102 is substantially perpendicular to the lower surface 230 of the base portion 224. Consequently, the orientation of the lower surface 230 of base portion 224 can be used to align the vertical light source package 100 so that the light from the light emitting device 102 is emitted in a desired direction.

In this embodiment, the structural body 107 is a single integral structure. Thus, the base portion 224 and the cylindrical portion 226 of the structural body 107 are integrated parts of a monolithic element. However, in other embodiments, the base portion 224 and the cylindrical portion 226 of the structural body 107 may be separate structures that are attached together to form the structural body. In the illustrated embodiment, the structural body 107 is made of a plastic material such as polyamide (PA) material. As an example, the structural body 107 may be made of Amodel or Xydar (both registered U.S. trademarks of Solvay Advanced Polymers, LLC). However, in other embodiments, the structural body 107 may be made of a different material. The structural body 107 can be formed using injection molding or any other suitable method for the material used.

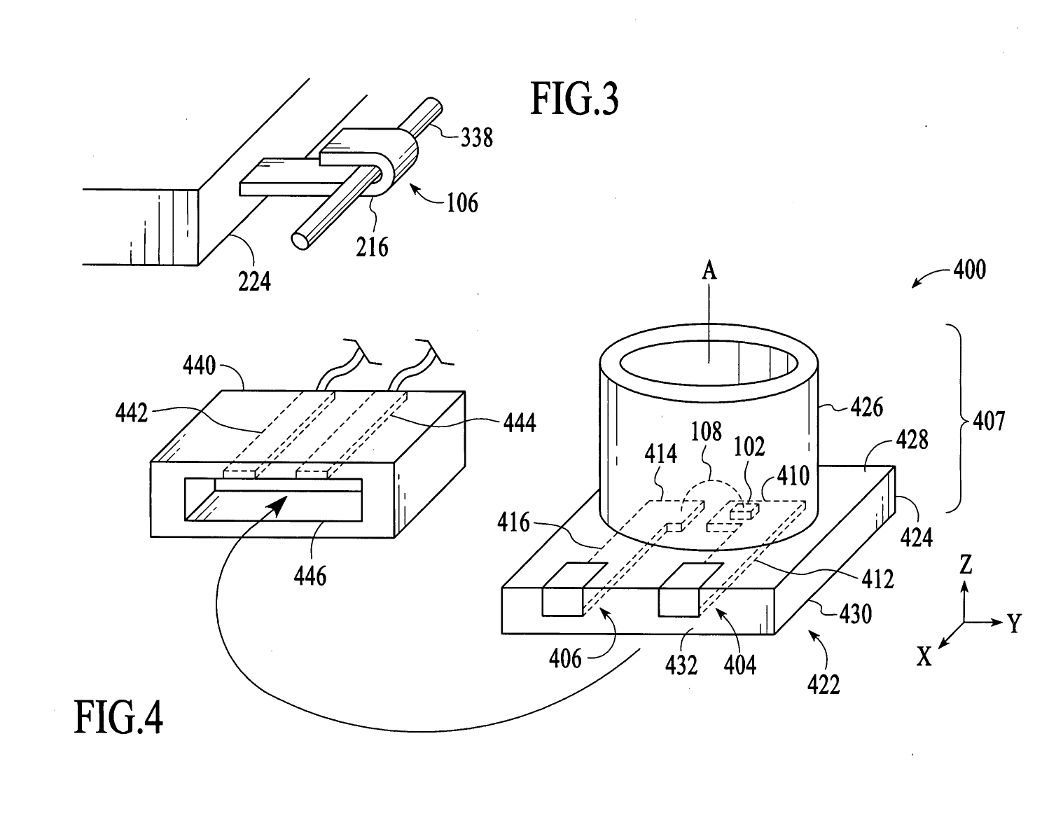

As shown in FIGS. 1 and 2, in this embodiment, each of the leads 212 and 216 of the leadframes 104 and 106, respectively, includes a hole 236 at the end of that lead, which is external to the structural body 107. The holes 236 of the leads 212 and 216 allow the leadframes 104 and 106 of the vertical light source package 100 to be soldered directly to external wires (not shown) rather than being attached to a printed circuit board (PCB) as conventional VCSEL packages. Thus, the vertical light source package 100 does not require a PCB. In other embodiments, the leads 212 and 216 of the leadframes 104 and 106, respectively, may be configured in any form for direct wire connection, which eliminates the need for a PCB. As an example, in FIG. 3, the lead 216 of the leadframe 106 is configured in a “U” shaped form for mechanical clipping with an external wire 338.

Turning now to FIG. 4, a vertical light source package 400 in accordance with another embodiment of the invention is shown. The vertical light source package 400 of FIG. 4 is similar to the vertical light source package 100 of FIG. 1. Thus, the reference numbers used in FIG. 1 will be used to identify similar elements in FIG. 4. Similar to the vertical light source package 100, the vertical light source package 400 includes the light emitting device 102, leadframes 404 and 406 and a structural body 407.

Similar to the structural body 107 of the vertical light source package 100, the structural body 407 of the vertical light source package 400 includes a rectangular base portion 424 and a cylindrical portion 426, which are connected to each other. However, in this embodiment, the base portion 424 is longer in the X direction so that the base portion 424 can be used as a male connector to be inserted into a female connector 440. The electrical connections between the vertical light source package 400 and the female connector 440 will be described below.

The leadframes 404 and 406 of the vertical light source package 400 are similar to the leadframes 104 and 106 of the vertical light source package 100. The leadframe 404 includes a region 410 on which the light emitting device 102 is mounted. The leadframe 404 further includes a lead 412, which extends from the region 410 in the X direction. Similarly, the leadframe 406 includes a region 414 to which the bondwire 108 is connected. The leadframe 406 further includes a lead 416, which also extends from the region 414 in the X direction. However, in this embodiment, the ends of the leads 412 and 416 of the leadframes 404 and 406, respectively, are exposed on a side surface 432 and an upper surface 428 of the base portion 424 of the structural body 407. In other embodiments, the ends of the leads 412 and 416 of the leadframes 404 and 406, respectively, may be exposed only at the same side surface 432 and/or a lower surface 430. As illustrated in FIG. 4, the ends of the leads 412 and 416 of the leadframes 404 and 406, respectively, may be bent to be exposed at the upper surface 432 or the lower surface 430 of the structural body.

As shown in FIG. 4, the female connector 440 includes exposed electrodes 442 and 444, which are positioned on the internal upper surface of a slot 446. The slot 446 is shaped to receive the base portion 424 of the vertical light source package 400. When the base portion 424 of the vertical light source package 400 is inserted into the slot 446 of the female connector 440, the exposed leads 412 and 416 of the vertical light source package 400 at the upper surface 428 of the structural body 407 will contact the exposed electrodes 442 and 444 of the female connector 440. Thus, the vertical light source package 400 can receive driving signals through the connected female connector 440, which eliminates the need for the vertical light source package 400 to be attached to a PCB. The positions of the exposed electrodes 442 and 444 of the female connector 440 can be located at different places in the slot 446 if the vertical light source package 400 has the exposed leads 412 and 416 at different surfaces of the base portion 424.

Although specific embodiments of the invention have been described and illustrated, the invention is not to be limited to the specific forms or arrangements of parts so described and illustrated. The scope of the invention is to be defined by the claims appended hereto and their equivalents.

What is claimed is:

1. A vertical light source package comprising:
a structural body including a light output end;
a light emitting device positioned in said structural body such that light from said light emitting device is emitted from said light output end of said structural body;
a first leadframe being at least partially positioned in said structural body, said first leadframe including a first region and a first elongate lead that extends from said first region in a predefined direction, said light emitting device being situated on said first region of said first leadframe; and
a second leadframe being at least partially positioned in said structural body, said second leadframe including a second region and a second elongate lead that extends from said second region in said predefined direction, said light emitting device being electrically connected to said second region of said second leadframe.

2. The package of claim 1 wherein said light emitting device is a vertical-cavity surface-emitting laser.

3. The package of claim 1 wherein said light emitting device is electrically connected to said second region of said second leadframe by a bondwire.

4. The package of claim 1 wherein at least one of said first and second elongate leads protrudes from a side surface of said structural body.

5. The package of claim 4 wherein each of said first and second elongate leads has a hole for direct wire connection.

6. The package of claim 4 wherein each of said first and second elongate leads has U-shaped end for mechanical clipping with a wire.

7. The package of claim 1 wherein said structural body further includes a back surface at a back end, said back end being the opposite end of said light output end of said structural body, said back surface being substantially planar, said back surface further being substantially perpendicular to a light emitting direction of said light emitting device.

8. The package of claim 1 wherein said structural body includes a base portion having a lower surface, said lower surface being located at an opposite end of said structural body as said light output end.

9. The package of claim 8 wherein said first and second elongate leads are exposed at a surface of said base portion, said surface being one of an upper surface, a side surface and said lower surface of said base portion.

10. The package of claim 9 wherein said base portion of said structural body is configured to be inserted into a slot of a female connector with exposed electrodes so that said first and second elongate leads exposed at said surface of said base portion are electrically connected to said exposed electrodes of said female connector when said base portion is inserted into said slot of said female connector.

11. The package of claim 8 wherein said base portion of said structural body is rectangular in shape.

12. The package of claim 8 wherein said structural body includes a cylindrical portion connected to said base portion, the axis of said cylindrical portion being substantially perpendicular to said lower surface of said base portion.

13. The package of claim 12 wherein said cylindrical portion of said structural body includes a cylindrical shell.

14. A vertical light source package comprising:
a structural body including a light output end;
a vertical-cavity surface-emitting laser (VCSEL) die positioned in said structural body such that light from said VCSEL die is emitted from said light output end of said structural body;
a first leadframe at least partially positioned in said structural body, said first leadframe including a first region and a first elongate lead that extends from said first region in a predefined direction, said VCSEL die being situated on said first region of said first leadframe; and
a second leadframe at least partially positioned in said structural body, said second leadframe including having a second region and a second elongate lead that extends from said second region in said predefined direction, said VCSEL die being electrically connected to said second region of said second leadframe.

15. The package of claim 14 wherein at least one of said first and second elongate leads protrude from a side surface of said structural body.

16. The package of claim 15 wherein each of said first and second elongate leads has a hole for direct wire connection.

17. The package of claim 15 wherein each of said first and second elongate leads has U-shaped end for mechanical clipping with a wire.

18. The package of claim 14 wherein said structural body includes a rectangular base portion having a lower surface, said lower surface being located at an opposite end of said structural body as said light output end, said back surface further being substantially perpendicular to a light emitting direction of VCSEL die.

19. The package of claim 18 wherein said first and second elongate leads are exposed at a surface of said rectangular base portion, said surface being one of an upper surface, a side surface and said lower surface of said rectangular base portion.

20. The package of claim 19 wherein said rectangular base portion of said structural body is configured to be inserted into a slot of a female connector with exposed electrodes so that said first and second elongate leads exposed at said surface of said rectangular base portion are electrically connected to said exposed electrodes of said female connector when said rectangular base portion is inserted into said slot of said female connector.
